(19) United States
(12) Patent Application Publication
(10) Pub. No.: US 2023/0099697 A1
(43) Pub. Date: Mar. 30, 2023

(54) CONVERTER ASSEMBLY AND TEST STAND HAVING A CONVERTER ASSEMBLY

(71) Applicant: AVL List GmbH, Graz (AT)

(72) Inventors: Martin SCHMIDT, Langen (DE); Erwin REISINGER, Feldkirchen bei Graz (AT)

(73) Assignee: AVL List GmbH, Graz (AT)

(21) Appl. No.: 17/909,400

(22) PCT Filed: Mar. 5, 2021
(86) PCT No.: PCT/AT2021/060080

§ 371 Date: Sep. 5, 2022

(30) Foreign Application Priority Data
Mar. 5, 2020 (AT) A50176/2020

(51) Int. Cl. H02M 5/458; G01R 31/40; B60L 50/51; H02M 1/14; H02M 3/10

(52) U.S. Cl. CPC H02M 5/458; G01R 31/40; B60L 50/51; H02M 1/14; H02M 3/10

(57) ABSTRACT

The invention relates to a converter assembly comprising a DC voltage intermediate circuit (1) for providing a DC voltage V_{DC}, comprising a positive terminal and a negative terminal, and at least one machine converter (2) for converting the DC voltage V_{DC} into a multi-phase AC voltage, wherein at least one energy storage capacitor (3, 3′) is arranged in the DC voltage intermediate circuit (1), and wherein a frequency-dependent resistor (4) which has a higher electrical resistance at high frequencies than at low frequencies is arranged in series with the energy storage capacitor (3, 3′).

The invention relates to a converter assembly for converting a DC voltage into an AC voltage or another DC voltage and a test stand with such a converter assembly.

Electrical converter assemblies for converting a DC voltage into an AC voltage (inverters) or into a DC voltage with a different voltage level (DC converters) are known from the prior art. These use, for example, switched inverters with semiconductor bridge circuits which replicate a sinusoidal AC voltage of short pulses of high frequency (a few kHz to over 20 kHz) by means of a modulation process, for example pulse width modulation (PWM). Such inverters are also known as sine wave inverters. The semiconductor switches switch the DC voltage on and off at high frequency; the mean value of the high-frequency, pulse-width-modulated switching frequency is the output AC voltage.

Such switched inverters are used in particular in test stands for vehicles. In such test stands, the electrical power required for the load machines is provided via a central DC voltage intermediate circuit or a battery, and inverters (so called machine converters) convert the DC voltage into the AC voltage required for the respective electrical load machine, for example an electric motor. Switched DC voltage converters may also be provided to generate a DC voltage with a different polarity or voltage curve.

Such converters can in particular be designed for bidirectional operation (so-called active front-end converters), so that they can both draw electrical power from the DC voltage intermediate circuit and also transfer it back.

As a rule, energy storage capacitors with very high capacitance are arranged in the DC voltage intermediate circuit to stabilise the provided DC voltage. These must be suitable for a DC voltage in the range of around 850 V. Slow capacitors, i.e. capacitors which are not suitable for high frequencies, are usually used as energy storage capacitors, usually being arranged in a control cabinet in the form of separate capacitor banks. The length of the supply lines results in relatively high inductances, so that in a conventional arrangement the energy storage capacitors are only slightly affected by high-frequency interference (ripple currents).

However, when using such converter assemblies in modern test stands, the problem arises that the dynamic test samples to be tested, i.e. the useful signals to be transmitted to the device under test, have a high frequency, for example several hundred Hertz up to 1000 Hz. At the same time, the energy storage capacitors should be arranged as close as possible to the switched inverter in order to make possible a compact design. As a result, the high-frequency interference generated by the switched inverters influences the energy storage capacitors.

An object of the invention is, on the one hand, to ensure that the high-frequency interference is dissipated without placing an undue load on the energy storage capacitors, and on the other hand to ensure that the energy storage capacitors can follow the comparatively low frequency useful signals. The aim is to make possible a compact converter assembly that can be used as a machine converter (DC-AC converter) or DC converter (DC-DC converter) in a test stand for vehicles, without the need for long connecting cables to the energy storage capacitors, without interfering excessively with the DC voltage intermediate circuit and without burdening the driven electric machine with ripple currents.

According to the invention, these and other objectives are achieved by a converter assembly and a test stand according to the independent claims.

A converter assembly according to the invention comprises a DC voltage intermediate circuit for providing a DC voltage V_{DC}, comprising a positive terminal and a negative terminal, and at least one converter. The converter can be a machine converter (DC-AC converter) for converting the DC voltage V_{DC} into a multiphase AC voltage. However, it can also be a bidirectionally operated line converter (AC-DC converter) that transfers excess electrical energy from a DC voltage intermediate circuit back into a multiphase network. The converter according to the invention can also be a DC converter (DC-DC converter) that converts the DC voltage V_{DC} into a DC voltage of different polarity or voltage level.

Where the converter assembly is used in a test stand, the DC voltage intermediate circuit can have a DC voltage V_{DC} in the range of around 850 V or above. In other applications, the DC voltage intermediate circuit may also have a lower DC voltage; for example, when using the converter assembly according to the invention in a vehicle (automotive sector), a voltage in the intermediate circuit V_{DC} of around 48 V may be provided.

One or more energy storage capacitors are arranged in the DC voltage intermediate circuit between the positive terminal and the negative terminal, wherein a frequency-dependent resistor which has a higher electrical resistance at high frequencies than at low frequencies is connected in series with the energy storage capacitor.

This ensures that low-frequency useful signals can be received and buffered by the energy storage capacitors, while high-frequency interference, such as typically occurs with high-frequency switched inverters, in particular with sine wave inverters, is blocked. Consequently, the energy storage capacitors are protected and a direct arrangement of the energy storage capacitors on the inverter is possible.

According to the invention, the frequency-dependent resistor can have an electrical resistance at high frequencies, in particular at frequencies above 10 kHz, above 16 kHz or above 20 kHz, which is higher by a multiple, preferably by at least a factor of 10, a factor 12, or a higher factor, than at low frequencies, in particular at frequencies below 500 Hz. The resistance at frequencies below 500 Hz can in particular be in the milliohm range.

The frequency-dependent resistor thus assumes the function of protecting the energy storage capacitors from high-frequency currents, whereby the specific cut-off frequency can however depend on the application. For example, certain applications of the converter assembly in vehicles (automotive sector) can require cut-off frequencies of around 150 kHz, so that the resistor still has a low resistance even at frequencies of around 150 kHz, and only assumes a significantly higher electrical resistance at frequencies in the range of 2 MHz.

In particular, according to the invention the energy storage capacitor may be a particularly high-storage storable capacitor with a capacitance of over 1 mF, preferably 6 mF, for example an electrolytic capacitor. However, other types of capacitors are also possible according to the invention. In the automotive sector in particular, at very high frequencies, for example frequencies above 150 kHz, the energy storage capacitors may be designed not as electrolytic capacitors, but as film or ceramic capacitors. Electrolytic capacitors are preferably not used in this application.

According to the invention, at high DC voltages in the DC voltage intermediate circuit, especially at DC voltages of over 500 V, a first energy storage capacitor and a second energy storage capacitor, connected in series, may be provided.

In this case, the frequency-dependent resistor can be arranged in series between the first energy storage capacitor and the second energy storage capacitor. More than two energy storage capacitors can also be arranged in series. Furthermore, a parallel connection of several energy storage capacitors may also be provided according to the invention.

One or more particularly alternating-load-resistant intermediate circuit capacitors can be arranged parallel to the energy storage capacitor. These serve to dissipate high-frequency interference, in particular interference generated by the switched inverters. The ratio of the capacitance of the energy storage capacitor to the capacitance of the intermediate circuit capacitors may preferably be greater than 5, particularly preferably greater than 10. For example, the intermediate circuit capacitors may have a capacitance of 180 μF, and the energy storage capacitors a capacitance of 1 mF.

According to the invention, the intermediate circuit capacitors may be designed in the form of film capacitors and/or ceramic capacitors. However, other types of capacitors are also possible according to the invention. In particular, the intermediate circuit capacitors can be realised through the parallel and series connection of individual capacitors.

For example, first intermediate circuit capacitors may be provided as film capacitors with a cut-off frequency of around 100 kHz, and second intermediate circuit capacitors as ceramic capacitors with a cut-off frequency of 1 MHz and above. The latter may be in particular be so-called CeraLink ceramic capacitors, which have a particularly low inductance at a particularly high cut-off frequency. As a result, a particularly good dissipation of even very high-frequency interference is achieved without placing an undue load on the energy storage capacitors. These embodiments are recommended when using a converter assembly according to the invention in a test stand.

According to the invention, in this case the capacitors may be designed for a DC voltage of over 350V, preferably over 500V, more preferably around 850 V or around 1400 V.

On the other hand, when using a converter assembly according to the invention in a vehicle, the intermediate circuit voltage is significantly lower, for example in the range of 48 V, and the switching frequencies significantly higher, so that, rather than electrolytic capacitors, only ceramic capacitors and film capacitors are used according to the invention. In this case, the first and/or second intermediate circuit capacitors may be designed as film capacitors or ceramic capacitors with a cut-off frequency in the range of around 2 MHz.

In a preferred embodiment of the invention, two energy storage capacitors, connected in series, are provided which are arranged on a circuit board or another carrier, wherein the frequency-dependent resistor is arranged between these components, namely on the underside of the circuit board or the carrier. This results in a particularly space-saving integration of the arrangement according to the invention.

The frequency-dependent resistor may be substantially cylindrical in form with a longitudinal extension L and a diameter D. The diameter D can vary periodically along the longitudinal extension L by an average value D₀+/−ΔD, wherein D₀ is preferably around 10 mm and ΔD preferably around 1 mm.

A DC voltage source providing the DC voltage V_{DC} may be provided, for example a battery or a line converter in the form of a switched rectifier, which is designed to convert a multiphase supply voltage into a DC voltage.

The invention further comprises a test stand for a vehicle or any drive, for example an industrial drive with a converter assembly according to the invention.

Such a test stand may include a line converter, a converter assembly according to the invention and an electric machine driven by the generated AC voltage. The intermediate circuit voltage may thereby lie in the range of around 850 V and energy storage capacitors in the form of electrolytic capacitors as well as first and second intermediate circuit capacitors may be provided.

The invention further comprises a powertrain for a vehicle with an electric machine and a converter assembly according to the invention. In this case, the intermediate circuit voltage is around 48 V and the energy storage capacitors are designed for a signal frequency of up to 150 kHz, i.e. the frequency-dependent resistor only blocks currents as from a frequency of more than 150 kHz. In this case, the energy storage capacitors are preferably film or ceramic capacitors. In contrast, the intermediate circuit capacitors are designed for a frequency in the range of around 2 MHz and are designed in the form of particularly alternating-load-resistant film or ceramic capacitors.

Further features according to the invention arise from the claims, the figures and the description of the exemplary embodiment.

The invention is explained in more detail below on the basis of a non-exclusive exemplary embodiment, whereby:

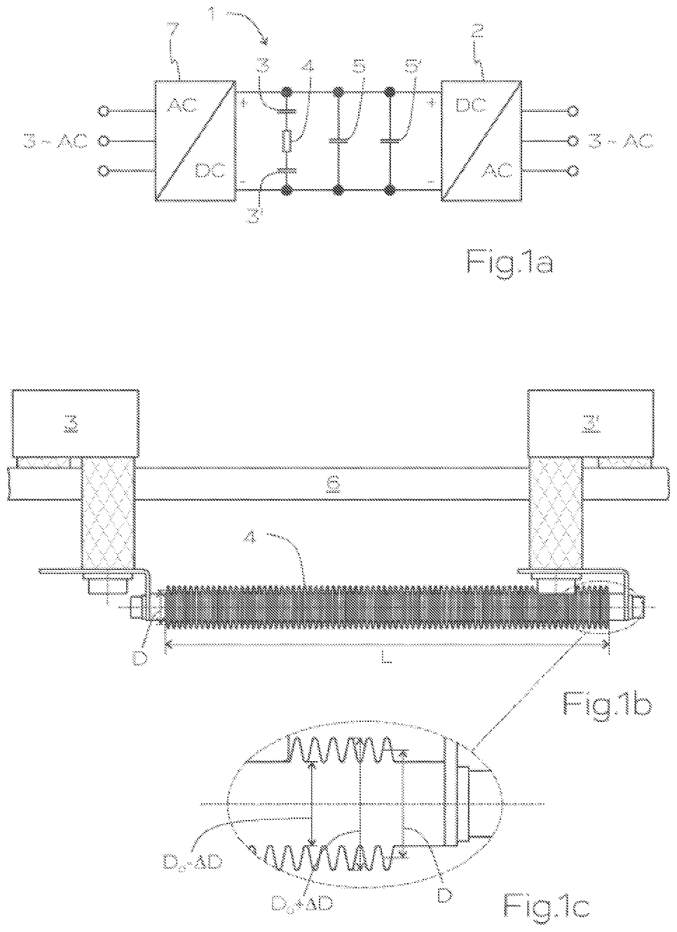

FIG. 1a: shows a schematic circuit diagram of a converter assembly according to the invention;

FIG. 1b: shows a schematic cross-section through an embodiment of a frequency-dependent resistor according to the invention;

FIG. 1c: shows a detail from FIG. 1b.

FIG. 1a shows a schematic circuit diagram of a converter assembly according to the invention for use in a test stand for vehicles. The converter assembly includes a DC voltage intermediate circuit 1 with a DC voltage of around 850 V which is provided by a line converter 7.

The DC voltage intermediate circuit 1 supplies a machine converter 2, which is operated as a switched inverter. This provides an AC voltage for the operation of an electric load machine for the test stand, for example an electric motor.

The DC voltage intermediate circuit has a positive terminal and a negative terminal. Two energy storage capacitors 3.3′ are arranged in series connection between the positive terminal and the negative terminal, whereby a frequency-dependent resistor 4 is arranged between the two energy storage capacitors 3.3′. In this exemplary embodiment, the energy storage capacitors 3, 3′ are electrolytic capacitors with a capacitance of around 1 mF. Intermediate circuit capacitors 5, 5′ are arranged in parallel with the energy storage capacitors 3, 3′. These have a lower capacitance, for example in the range of 180 μF, and serve to dissipate high-frequency interference.

Both the energy storage capacitors 3, 3′, and the intermediate circuit capacitors 5, 5′ are located in the immediate vicinity of the switched converters, namely the line converter 7 and the machine converter 2. In the present embodiment, two types of intermediate circuit capacitors are used, on the one hand ceramic CeraLink capacitors for very fast currents up to a cut-off frequency of 1 MHz, and on the other hand film capacitors for currents up to a cut-off frequency of around 100 kHz. The intermediate circuit capacitors 5, 5′ are in each case designed for a voltage of 850 V and are connected directly to the intermediate circuit with low inductance, i.e. avoiding long connecting cables.

In this exemplary embodiment, the energy storage capacitors 3, 3′ are also directly connected to the intermediate circuit, so that only low line inductances occur. In order to keep the ripple current load of the energy storage capacitors 3.3′ low, while still making possible test samples with high-frequency current changes of up to around 1000 Hz, a frequency-dependent resistor 4 is connected in series with the energy storage capacitors 3, 3′.

In an exemplary embodiment which is not illustrated, several parallel branches with energy storage capacitors and frequency-dependent resistors are provided to increase the overall storage capacity of the converter.

The frequency-dependent resistor 4 is relatively low-impedance for frequencies below 1000 Hz, and relatively high-impedance for switching-frequency-proportional currents, i.e. currents with a frequency of 16 kHz or above. In this exemplary embodiment, the ratio between the electrical resistance at frequencies of 16 kHz and 500 Hz is around 12. This prevents the energy storage capacitors 3,3′, which are coupled with low inductance, from being unduly loaded with the high switching frequency. Consequently, no excessive heating of the energy storage capacitors 3, 3′ occurs, and these can be utilised more efficiently.

FIG. 1b shows a schematic cross-section through an embodiment of a frequency-dependent resistor 4 according to the invention. In this embodiment, the frequency-dependent resistor 4 is designed in such a way that the electrical skin effect is exploited: at high electrical frequencies, the electric current is displaced to the outer surface of the resistor; the outer surface area is increased through a periodic variation of the diameter, resulting in an increased electrical resistance. This property of the skin effect is used here, advantageously, to make use of a nonlinear ohmic resistance to protect the already-mentioned energy storage capacitor from high-frequency currents. The advantage of such an embodiment is that the frequency-dependent resistor 4 according to the invention is designed, as protection for the energy storage capacitor 3, as a nonlinear and non-oscillating resistor 4 and does not require oscillating components such as an impedance or a capacitance. Thus, the capacitance of the energy storage capacitor 3 is freely selectable and not coupled to a frequency, as is for example the case with an oscillating circuit.

A schematically indicated first energy storage capacitor 3 and a second energy storage capacitor 3′, connected in series, are provided, wherein the frequency-dependent resistor 4 is arranged in series between the first energy storage capacitor 3 and the second energy storage capacitor 3′. The two energy storage capacitors 3, 3′ are arranged on a circuit board 6, and the frequency-dependent resistor 4 is arranged on the underside of this circuit board 6.

FIG. 1c shows a detail from FIG. 1b, namely the shape of the frequency-dependent resistor 4. The frequency-dependent resistor 4 is substantially cylindrical in form with a longitudinal extension L and a diameter D. The diameter D varies along the longitudinal extension L by an average value D₀+/−ΔD periodically, wherein D₀ is around 10 mm and ΔD around 1 mm.

An exemplary embodiment of the invention, not illustrated, comprises a test stand for a vehicle with a line converter 7, a converter assembly according to the invention and an electric machine driven by the generated AC voltage.

However, the invention is not limited to the present exemplary embodiments, but includes all devices within the framework of the following claims.

Terms used herein such as converter, line converter or machine converter should not be interpreted too narrowly. A converter according to the invention, be it a machine converter or a line converter, can be understood as any controlled electrical and/or electronic circuit that converts one DC voltage into another DC voltage or AC voltage, or converts an AC voltage into another AC voltage or DC voltage. Such a circuit may for example, but not exclusively, be a direct converter, a matrix converter, an AC voltage converter, a DC voltage converter, a switched bridge inverter, a switched bridge rectifier or the like. The concrete realisation of the converter in terms of circuitry is not critical. Converters provided according to the invention can also feature internal galvanic isolation and can be intended for high electrical powers, for example powers in the region of 100 kW at a DC voltage of 850 V or 300 kVA alternating current power.

### LIST OF REFERENCE SYMBOLS

1 DC voltage intermediate circuit
2 machine converter
3, 3′ energy storage capacitor
4 resistor
5, 5′ intermediate circuit capacitor
6 circuit board
7 line converter

1. Converter assembly, comprising
a. a DC voltage intermediate circuit for providing a DC voltage V_{DC}, comprising a positive terminal and a negative terminal, and
b. at least one converter, in particular a machine converter, for converting the DC voltage V_{DC} into an AC voltage or into another DC voltage,
1. wherein at least one energy storage capacitor is arranged in the DC voltage intermediate circuit between the positive terminal and the negative terminal, wherein a frequency-dependent resistor which has a higher electrical resistance at high frequencies than at low frequencies is connected in series with the energy storage capacitor, characterised in that at high frequencies, in particular at frequencies above 10 kHz, the frequency-dependent resistor has an electrical resistance which is higher by a multiple, preferably by at least a factor of 10 or a factor of 12, than at low frequencies, in particular at frequencies below 500 Hz.

2. Converter assembly according to claim 1, wherein the energy storage capacitor is a particularly high-storage capacitor with a capacitance of over 1 mF, preferably 6 mF, for example an electrolytic capacitor.

3. Converter assembly according to claim 1, wherein a first energy storage capacitor and a second energy storage capacitor, connected in series, are provided, wherein the frequency-dependent resistor is arranged in series between the first energy storage capacitor and the second energy storage capacitor.

4. Converter assembly according to claim 1, wherein one or more particularly alternating-load-resistant intermediate circuit capacitors are arranged parallel to the energy storage capacitor, wherein the ratio of the capacitance of the energy storage capacitor to the capacitance of the intermediate circuit capacitors is preferably greater than 5, particularly preferably greater than 10.

5. Converter assembly according to claim 4, wherein the intermediate circuit capacitors are designed in the form of film capacitors and/or ceramic capacitors.

6. Converter assembly according to claim 4, wherein the intermediate circuit capacitors are realised through the parallel and series connection of individual capacitors.

7. Converter assembly according to claim 4, wherein first intermediate circuit capacitors are designed as film capacitors with a cut-off frequency of around 100 kHz.

8. Converter assembly according to claim 5, wherein second intermediate circuit capacitors are designed as ceramic capacitors with a cut-off frequency of 1 MHz and above.

9. Converter assembly according to claim 1, wherein the capacitors are designed for a DC voltage of over 350V, preferably over 500V, more preferably around 850 V or around 1400 V.

10. Converter assembly according to claim 3, wherein the two energy storage capacitors are arranged on a circuit board or another carrier and the frequency-dependent resistor is arranged on the underside of this circuit board or the carrier.

11. Converter assembly according to claim 1, wherein the frequency-dependent resistor is substantially cylindrical in form with a longitudinal extension L and a diameter D.

12. Converter assembly according to claim 11, wherein the diameter D varies periodically along the longitudinal extension L by an average value D₀+/−ΔD, wherein D₀ is preferably around 10 mm and ΔD preferably around 1 mm.

13. Converter assembly according to claim 1, wherein a DC voltage source providing the DC voltage V_{DC} is provided, for example a battery or a line converter, which is designed to convert a multiphase supply voltage into a DC voltage.

14. Test stand for a vehicle or a drive, comprising a line converter, a converter assembly according to claim 1 and an electric machine driven by the AC voltage.

15. Powertrain for a vehicle with an electric motor and a converter assembly according to claim 1.
